(19) United States
(12) Patent Application Publication
(10) Pub. No.: US 2025/0362326 A1
(43) Pub. Date: Nov. 27, 2025

(54) HIGH-BANDWIDTH CURRENT SENSOR WITH ADAPTIVE COMPENSATION FOR PARASITIC RESISTANCE

(71) Applicant: VIRGINIA TECH INTELLECTUAL PROPERTIES, INC., Blacksburg, VA (US)

(72) Inventors: Xingchen Zhao, San Jose, CA (US); Dong Dong, Blacksburg, VA (US); Rolando Burgos, Blacksburg, VA (US)

(21) Appl. No.: 18/672,703

(22) Filed: May 23, 2024

(51) Int. Cl. G01R 19/00; G01R 35/00

(52) U.S. Cl. CPC G01R 19/0092; G01R 35/005

(57) ABSTRACT

An example current sensor for a power converter includes a sensing circuit configured to generate an output voltage based on a device current flowing through a power converter. The output voltage is representative of a measurement of the device current. The current sensor can further include a compensation circuit electrically coupled to the sensing circuit, and the compensation circuit can include a compensation resistor and a processor. The compensation circuit can be configured to receive the output voltage and adjust an error of the output voltage as compared to the device current. The error can be caused by a parasitic resistance existing in the power converter.

### BACKGROUND

Current sensors for measuring current of power devices, such as wide-band gap (WBG) power converters, generally require high-bandwidth and high-accuracy sampling of device current. Information obtained from device current can be used for device characterization, short-circuit protection, load current reconstruction, and other purposes. Existing current sensors for power converters can produce extra loss, require extra space, and increase the commutation loop inductance.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 depicts an example schematic of a current sensor electrically coupled to a power converter according to one or more embodiments of the present disclosure.

FIG. 2 depicts a timing diagram for adaptive compensation of parasitic resistance based on device off-time sampling for the current sensor shown in FIG. 1 according to one or more embodiments of the present disclosure.

FIG. 3 depicts a timing diagram for adaptive compensation of parasitic resistance based on device on-time and off-time sampling for the current sensor shown in FIG. 1 according to one or more embodiments of the present disclosure.

FIG. 4 depicts an example schematic of the power converter shown in FIG. 1 electrically connected to the current sensor also shown in FIG. 1 according to one or more embodiments of the present disclosure.

FIG. 5 depicts a resistor capacitor (RC) circuit for modeling the bandwidth of the current sensor shown in FIG. 1 according to one or more embodiments of the present disclosure.

FIG. 6 is a flowchart of an example method for adaptive compensation of parasitic resistance for the current sensor shown in FIG. 1 according to one or more embodiments of the present disclosure.

### DETAILED DESCRIPTION

Power conversion devices and systems are relied upon to convert electric power or energy from one form to another. A power converter is an electrical or electro-mechanical device or system for converting electric power or energy from one form to another. As examples, power converters can convert alternating current (AC) power into direct current (DC) power, convert DC power to AC power, provide DC-to-DC conversion, provide AC-to-AC conversion, change or vary the characteristics (e.g., the voltage rating, current rating, frequency, etc.) of power, or offer other forms of power conversion. A power converter can be as simple as a transformer, but many power converters have more complicated designs and are tailored for a variety of applications and operating specifications.

Current sensors for measuring current of power devices, such as wide-band gap (WBG) power converters, generally require high-bandwidth and high-accuracy sampling of device current. Information obtained from device current can be used for device characterization, short-circuit protection, load current reconstruction, and for other purposes. The conventional shunt resistor, for example, can produce extra loss, take extra space, and increase the commutation loop inductance. Alternative current sensors such as Rogowski coils and current transducers can require a large amount of extra space, and the parasitic capacitance of the coils can lead to limited bandwidth.

The parasitics in the power loop of power converters can be a potential tool to provide the current information of the power converters with high bandwidth, high density, and low cost. For example, parasitic resistances and inductances can be inherent in all conductive components, including spacers, printed circuit board (PCB) traces, and bonding wires within power devices. In contrast to external current sensors such as the ones described above, the current sensors described according to the embodiments of the present disclosure can use the inherent parasitics present in power converters to measure device current, leading to high bandwidth, high density, low cost, and other advantages.

There have been previous efforts to use the above-described parasitics for current sensing, but these approaches face limitations. For example, one previous approach relied on total impedance of a PCB trace that encompasses parasitic resistance and inductance, but this approach required complex offline simulations and computations at different frequencies, limiting its widespread applicability. The resistance of the parasitic resistance further prevented the popularization of this method.

In another approach, parasitic resistance in a bonding wire of a power module was used for current reconstruction with the influence of parasitic inductance mitigated through resistance capacitor (RC) low-pass filters. However, sensitivity to temperature and frequency rendered the gain of these sensors unfixed over a wide operational range.

In contrast, parasitic inductance can remain insensitive to temperature and frequency variations, offering a stable gain for current sensors. An RC low-pass filter can capture high frequency components of device current but can fail to reconstruct low frequency components. For example, even when employing active integrators, distortion can persist in the low frequency components due to parasitic resistance, leaving a gap in the full picture of device current. However, the influence of parasitic resistance can be difficult to mitigate or eliminate, as the value of the parasitic resistance can be difficult to obtain and is sensitive to temperature.

According to the embodiments described herein, a current sensor for a power converter includes a sensing circuit configured to generate an output voltage based on a device current flowing through a power converter, where the output voltage is representative of a measurement of the device current. In addition, a compensation circuit can be electrically coupled to the sensing circuit, with the sensing circuit including a compensation resistor and a processor. The compensation circuit can be configured to receive the output voltage and adjust an error of the output voltage as compared to the device current, where the error can be caused by a parasitic resistance existing in the power converter. The current sensor of the embodiments is capable of real-time, high accuracy, and high-bandwidth device current reconstruction based on parasitics, while also eliminating the influence of parasitic resistance under various operational conditions, without prior knowledge of resistance values. The current sensor can reduce costs and space required for implementation with various power converters, as compared to external current sensors that are placed in power loops. The current sensor can provide information of the power device to which it is connected such as current information, at high-bandwidth, high density, and low cost.

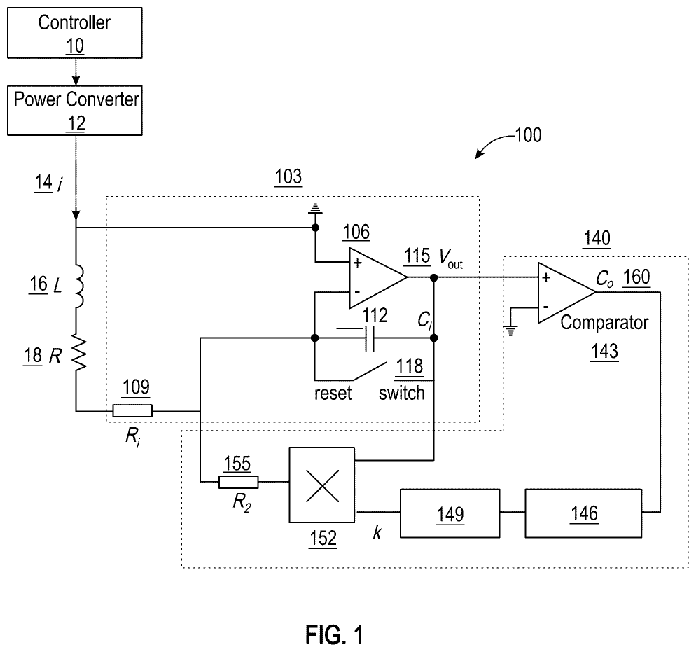

With reference to the drawings, FIG. 1 depicts an example schematic of a current sensor 100 electrically coupled to a power converter 12, according to one or more embodiments of the present disclosure. FIG. 1 is not exhaustively illustrated, meaning that other components that are not shown in FIG. 1 can be included or relied upon in some cases. Similarly, one or more components shown in FIG. 1 (e.g., components of the current sensor 100) can be omitted in some cases. The current sensor 100 can be electrically connected to the power converter 12 at a location or connected trace where device current measurement is desired. The current sensor 100 can provide adaptive compensation for the device current measurements, to mitigate or effectively cancel effects of parasitic resistance existing in a connected trace of the power converter 12. The current sensor 100 can be electrically coupled to the power converter 12 at various PCB traces, wires, wire bonds, Kelvin and source connections, and/or any conductive components of the power converter 12 where device current may flow, to measure device current 14 flowing through the conductive components. For example, the current sensor 100 can be electrically coupled between a switch and a voltage source of the power converter 12, to measure device current flowing from the switch while providing adaptive compensation for parasitic resistance.

The current sensor 100 can include a sensing circuit 103 configured to measure the device current 14 and a compensation circuit 140 configured to provide adaptive compensation for the parasitic resistance existing in the connected trace of the power converter 12. The sensing circuit 103 can include an operational amplifier (op-amp) 106, an integrator resistor 109 (“Rᵢ”), an integrator capacitor 112 (“Cᵢ”), and/or a reset switch 118 for measuring the device current 14. The sensing circuit 103 is an integrator circuit configured to measure the device current 14 by utilizing inherent parasitic components existing in the connected trace of the power converter 12. For example, the sensing circuit 103 can be configured to integrate a voltage presented across the parasitic inductance 16 to provide a sensor output or voltage output 115 by way of the op-amp 106. To provide the voltage output 115, the op-amp 106 can be electrically connected to the integrator capacitor 112, the integrator resistor 109, and the reset switch 118. The reset switch 118 can be used to reset the current sensor 100 between various on-times and off-times of the power converter 12.

The compensation circuit 140 is electrically coupled to the sensing circuit 103 and can include a comparator 143, a processor 146, a digital-to-analog converter (DAC) 149, a multiplier 152, and a compensation resistor 155 (“R₂”). The compensation circuit 140 can be configured to substantially mitigate or cancel the effects of parasitic resistance(s) on the measurement of the device current 14. For example, the compensation circuit 140 can be configured to cancel or mitigate influence of parasitic resistance 18 on the device current 14 measured by the sensing circuit 103. The processor 146 can include a field programmable gate array (FPGA) or any other programmable logic devices or processors.

The comparator 143 is electrically coupled to the op-amp 106 and configured to receive the voltage output 115 from the op-amp 106. The comparator 143 can be configured to determine a polarity of the voltage output 115 during on-times and/or off-times of the power converter 12. Based on the determined polarity, the processor 146 and/or the DAC 149 can be configured to dynamically adjust a compensation coefficient k. The dynamically adjusted compensation coefficient k and the compensation resistor 155 can be used to cancel the effects of the parasitic resistance 18 so that the current sensor 100 provides accurate current sensing of the device current 14.

The current sensor 100 can be implemented on a PCB with various other components such as the power converter 12, a gate driver, and other components of a power converter system that may be needed for operation of the power converter 12. As previously discussed, the current sensor 100 requires minimal space requirements and can be easily implemented within a PCB with the power converter 12, enabling the current sensor 100 to be implemented with a wide range of power converter systems. For example, the current sensor 100 can be implemented on a PCB with a footprint that can accommodate the sensing circuit 103 and the compensation circuit 140. For example, the footprint of the PCB can correspond to approximately 20-23 mm in width and approximately 25-29 mm in length, and vice-versa, according to various examples.

The power converter 12 can include various types of isolated and/or non-isolated power converters such as buck, boost, buck-boost, and Ćuk power converters. The power converter 12 can include WBG devices, such as Gallium-Nitride (GaN) and Silicon-Carbon (SiC) devices, which can operate at higher switching frequencies, greater efficiency, and higher power density than other devices. In many applications, including data center, telecom, energy storage, electric vehicle (EV), wireless power transfer, solid-state transformer, and other applications, WBG devices have been applied to offer a range of benefits. The switching frequency of power converters can be pushed to several hundred kHz or MHz using WBG devices. The use of higher switching frequencies facilitates reduced size and number of passive components, such as magnetics and capacitors, and printed circuit board (PCB) windings can be adopted for planar transformers and inductors, represented by the power converter 12.

The controller 10 can be configured to control the power converter 12 by generating control signals for the power converter 12. The control signals can direct the switching (i.e., current or power flow) operation of the power converter 12. Example operating frequencies for the power converter 12 can range from tens of kHz to several MHz or higher. The switching devices and operation of the power converter 12 can be controlled by pulse width modulation (PWM) control signals generated by the controller 10, as one example.

To measure the device current 14, the sensing circuit 103 can be configured to generate the voltage output 115 (“Vₒᵤₜ”) or the sensor output of the op-amp 106, based on integrating the voltage presented across the parasitic inductance 16 over time. The outcome of this integration process can lead to the reconstruction of the current profile of the device current 14, and the measurement of the device current 14 by the sensing circuit 103 can be determined based on the voltage output 115. For example, the op-amp 106 can be configured to generate the voltage output 115 based on the equation below:

$${V}_{out} = \frac{1}{{sR}_{i} {C}_{i}} {V}_{i} = \frac{1}{{sR}_{i} {C}_{i}} sLi = \frac{iL}{{R}_{i} {C}_{i}} , \qquad ( 1 )$$

where Vᵢ is the voltage across the parasitic inductance 16, and the integrator resistor 109 and the integrator capacitor 112 are the resistance and capacitance of the sensing circuit 103, respectively. According to equation (1), the gain of the proposed sensor G is described in the following equation:

$$G = \frac{L}{{R}_{i} {C}_{i}} , \qquad ( 2 )$$

However, the presence of parasitic resistance 18 in the utilized trace can introduce another proportional part in the induced voltage Vᵢ across the parasitic inductance 16. The impact of the parasitic resistance 18 is described by equation (3) listed below:

$${V}_{out} = \frac{{V}_{i}}{{sR}_{i} {C}_{i}} = \frac{i ( R + sL )}{{sR}_{i} {C}_{i}} = ( \frac{L}{{R}_{i} {C}_{i}} + \frac{R}{{sR}_{i} {C}_{i}} ) i , \qquad ( 3 )$$

which represents the transfer function of the current sensor 100 while accounting for the parasitic resistance 18. Analysis of equation 3 reveals that the parasitic resistance 18 can cause a zero in the voltage Vᵢ across the connected trace (e.g., across the parasitic inductance 16) of the sensing circuit 103 and the power converter 12 and can thus add one integral portion to the voltage output 115 as compared to an ideal scenario where the parasitic resistance 18 may not be present. Therefore, a first-order circuit with one pole, such as the compensation circuit 140, can be used to cancel the effect of the influence of the parasitic resistance 18 on the voltage output 115.

The transfer gain of the current sensor 100 with compensation is derived as described in equations (4) and (5) below:

$$\frac{{V}_{out}}{i} = \frac{sL + R}{{sR}_{i} {C}_{i} + \frac{{R}_{i}}{{R}_{1}}} \qquad ( 4 )$$

$${R}_{1} = \frac{L}{{RC}_{i}} \qquad ( 5 )$$

If the value of R₁ is derived as described above in equation (5), equation (4) can be equivalized into equation (1), where the influence of the parasitic resistance 18 can be effectively eliminated, causing the current sensor 100 to work as an ideal proportional amplifier.

Although the influence of the parasitic resistance 18 can be effectively eliminated with R₁, a variable and programmable resistor R₁ is preferable considering the variation of the parasitic resistance 18. For example, a programmable resistor R₁ can correspond to the compensation resistor 155 (“R₂”) in FIG. 1, and the compensation resistor 155 and a coefficient k, generated via the processor 146 and the DAC 149, can enable the current sensor 100 to provide current sensing with adaptable and programmable compensation for the parasitic resistance 18. With the compensation resistor 155 and the coefficient k, equations (4) and (5) can be rewritten as (6) and (7), respectively:

$$\frac{{V}_{out}}{i} = \frac{sL + R}{{sR}_{i} {C}_{i} + \frac{{kR}_{i}}{{R}_{2}}} \qquad ( 6 )$$

$$\frac{{R}_{2}}{k} = \frac{L}{{RC}_{i}} \qquad ( 7 )$$

In various applications, obtaining the precise value of the parasitic resistance 18 can be challenging, and the sensitivity of the parasitic resistance 18 to temperature can further complicate obtaining calculations. Therefore, it is important to evaluate the influence of incorrect compensation for the parasitic resistance 18 to develop an automated method for adjusting the compensation to account for the above-mentioned uncertainties.

Assuming an error ΔR exists between an estimated parasitic resistance Rₑ used for the compensation and the real parasitic resistance R, as shown in equation (8) below:

$$Δ R = R - {R}_{e} , \qquad ( 8 )$$

The transfer function of the current sensor 100 can be derived as shown in equation (9) below:

$$\frac{{V}_{out}}{i} = \frac{L}{{R}_{i} {C}_{i}} ( 1 + \frac{Δ R}{sL + {R}_{e}} ) \qquad ( 9 )$$

Thus, the error between the voltage output 115 (e.g., the output of the sensor 100) and the device current 14 (i.e., real or actual device current of the power converter 12 at the connected trace) can be expressed by equation (10) below:

$${i}_{error} = \frac{Δ R}{sL + {R}_{e}} i \qquad ( 10 )$$

In most PWM converters, device current is generally in the form of continuous pulses, where the power converter is turned on at a time tₒₙ, and turned off at the time of t_{off}, for example. In the frequency domain, the pulse current can be expressed as equation (11) below:

$$i = \frac{I}{s} ( {e}^{- {st}_{on}} - {e}^{- {st}_{off}} ) , \qquad ( 11 )$$

where I is the steady-state current. According to equations (8) and (10), the voltage output 115 with the error ΔR can be derived as shown in equation (12) below:

$${V}_{out} = \frac{G \cdot I}{s} ( {e}^{- {st}_{on}} - {e}^{- {st}_{off}} ) + \frac{G \cdot I}{s} ( {e}^{- {st}_{on}} - {e}^{- {st}_{off}} ) \frac{Δ R}{sL + {R}_{e}} \qquad ( 12 )$$

Converting equation (12) to the time domain, the voltage output 115 can be expressed as equation (13) below:

$${V}_{out} = G \cdot I \cdot [ u ( t - {t}_{on} ) - u ( t - {t}_{off} ) ] + {V}_{out \_ error 1} + {V}_{out \_ error 2} + {V}_{out \_ error 3} , \qquad ( 13 )$$

where u(t) is the step function of the unity magnitude. Equation 13 can be broken into four parts. For example, the first part can correspond to the correct response of the sensor, as expressed in equation (14). The other three parts listed for equations (15)-(17) are the errors caused by the error ΔR. For example, equation (15) is the error induced by the rising edge of the device current, which is in the exponential form. Equation (16) corresponds to the steady-state error, which is proportional to the error ΔR. Equation (17) is the error corresponding to the falling edge of the device current 14.

$${V}_{out 1} = G \cdot I \cdot [ u ( t - {t}_{on} ) - u ( t - {t}_{off} ) ] \qquad ( 14 )$$

$${V}_{out \_ error 1} = \frac{- G \cdot I \cdot Δ R}{{R}_{e}} {e}^{- \frac{{R}_{e}}{L} ( t - {t}_{on} )} u ( t - {t}_{on} ) \qquad ( 15 )$$

$${V}_{out \_ error 2} = \frac{G \cdot I \cdot Δ R}{{R}_{e}} [ u ( t - {t}_{on} ) - u ( t - {t}_{off} ) ] \qquad ( 16 )$$

$${V}_{out \_ error 3} = \frac{G \cdot I \cdot Δ R}{{R}_{e}} {e}^{- \frac{{R}_{e}}{L} ( t - {t}_{off} )} u ( t - {t}_{off} ) \qquad ( 17 )$$

The voltage output 115 and the total error can be defined based on the polarity of the error ΔR, which can correspond to over-compensation, correct compensation, or under-compensation. The polarity of the error ΔR can be identical to the polarity of the total output error. After the power converter 12 is turned off, the device current 14 is zero and the polarity of the output error can be identified by detecting the polarity of the voltage output 115.

To address the challenges of mitigating the effect of the parasitic resistance 18 on the voltage output 115, a closed-loop algorithm can be implemented in the current sensor 100 via the compensation circuit 140 to achieve automatic and accurate compensation for the parasitic resistance 18. For example, the compensation coefficient k can be dynamically adjusted by monitoring the polarity of the voltage output 115 after the power converter 12 is turned on and/or off. The comparator 143 can be used to identify the polarity of the voltage output 115, and the processor 146 can be used for modifying the compensating by altering the coefficient k.

In one example, when the comparator output 160 is positive based on the polarity of the voltage output 115 that is fed as an input, this could indicate a case of under-compensation (e.g., the error ΔR is positive). In such an example, the processor 146 can be configured to increase the coefficient k. The compensation resistor 155 and the coefficient k, generated and adjusted by the processor 146 and/or the DAC 149, can be used to effectively cancel or substantially reduce the effect of the parasitic resistance 18. In another example, when the comparator output 160 is negative based on the polarity of the voltage output 115, indicating a case of over-compensation (e.g., the error ΔR is negative), the coefficient k can be decreased. To eliminate the accumulated error of the op-amp 106 caused by the bias current and offset voltage, the sensing circuit 103 and/or the compensation circuit 140 can be reset some time after the power converter 12 is turned off.

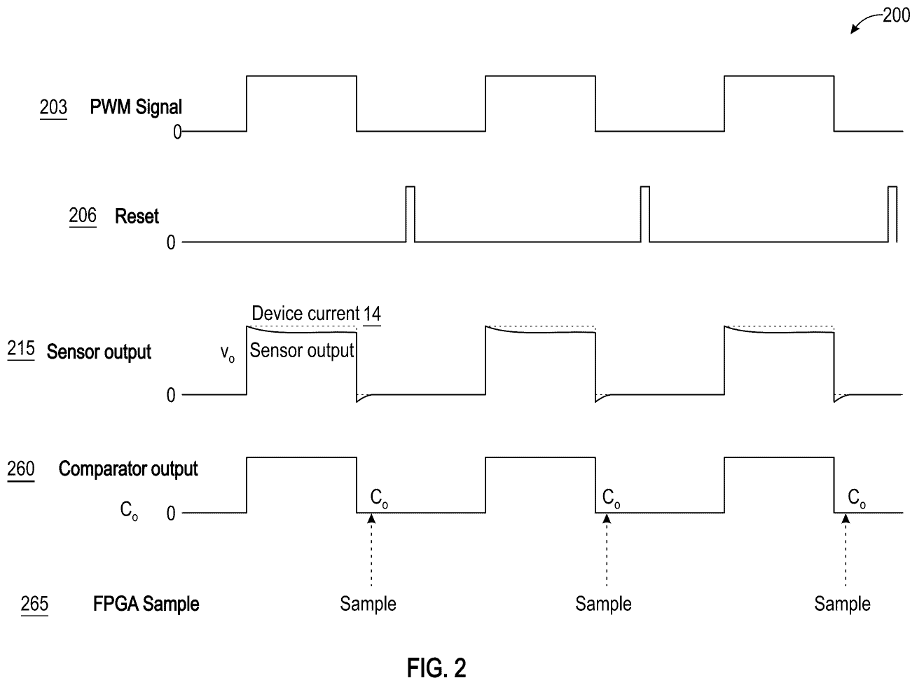

FIG. 2 depicts a timing diagram 200 for adaptive compensation of parasitic resistance according to one or more embodiments of the present disclosure. The timing diagram 200 illustrates components of a closed-loop control algorithm (e.g., PID control algorithm) for adaptive compensation by monitoring the polarity of the voltage output 115 after the power converter 12 is turned off. For example, an error (e.g., the error ΔR) can exist between a sensor output signal 215 and the device current 14 as illustrated in the timing diagram 200. As such, the current sensor 100 can be configured to implement adaptive compensation to mitigate or effectively cancel the parasitic resistance 18 via the compensation circuit 140 based on implementation of the timing diagram 200.

The timing diagram 200 illustrates waveforms for a PWM signal 203, a reset signal 206, the sensor output signal 215, a comparator output signal 260, and an FPGA sample signal 265. The controller 10 can be configured to generate the PWM signal 203 and the reset signal 206 for controlling the switching of the power converter 12, which can effectively drive the device current 14. The compensation circuit 140 can operate to effectively cancel the effect of the parasitic resistance 18 based on the PWM signal 203, by implementing the timing diagram 200 in a closed-loop control algorithm as described below.

The sensor output signal 215, the comparator output signal 260, and the FPGA sample signal 265 correspond to signals generated by the compensation circuit 140, for generating and modifying the compensation coefficient k. The sensor output signal 215 can correspond to the voltage output 115 that is generated by the op-amp 106. The comparator output signal 260 can correspond to the comparator output 160 that is generated by the comparator 143. The comparator output signal 260 can be used for determining the polarity of the sensor output signal 215 based on various samples of the FPGA sample signal 265 gathered by the processor 146 during the off-states of the PWM signal 203. For example, the FPGA sample signal 265 can include samples (e.g., “sample” corresponding to “Co”) of the comparator output signal 260 gathered after the PWM signal 203 is in an off-state. The processor 146 may gather the samples continuously over time for the length of the PWM signal 203, as illustrated in the timing diagram 200. The reset signal 206 can be used to synchronize the operation of the PWM signal 203 with the power converter 12 to reset internal states within the controller 10 and/or to reset operation of the current sensor 100.

In the timing diagram 200, the comparator output signal 260 is sampled during the off-states of the PWM signal 203. The sampling of the comparator output signal 260 at the illustrated instances of time can occur when the power converter 12 is turned off from the PWM signal 203 being in the off-state. If the sample of the comparator output signal 260 is positive, indicating a case of under-compensation (ΔR is positive), the processor 146 can be configured to increase the coefficient k. If the sample of the comparator output signal 260 is negative, indicating a case of over-compensation (ΔR is negative), the processor 146 can be configured to decrease the coefficient k.

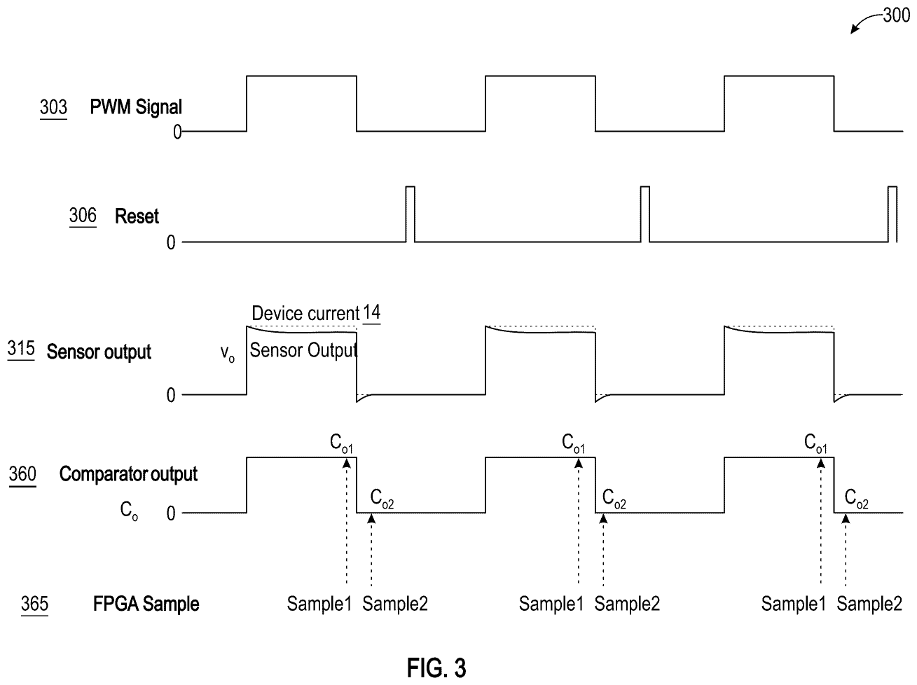

FIG. 3 depicts a timing diagram 300 for adaptive compensation of parasitic resistance according to one or more embodiments of the present disclosure. The timing diagram 300 illustrates components of a closed-loop control algorithm (e.g., PID control algorithm) for adaptive compensation by monitoring the polarity of the voltage output 115 before and after the power converter 12 is turned off. For example, an error (e.g., the error ΔR) can exist between a sensor output signal 315 and the device current 14 as illustrated in the timing diagram 300, and the polarity of the device current 14 can be negative during the on-times of the power converter 12. The current sensor 100 can be configured to implement adaptive compensation of the coefficient k by monitoring the polarity of the voltage output 115 during both the on-times and off-times of the power converter 12. In contrast to the timing diagram 200, the logic of close-loop adjustment of coefficient k is determined by monitoring the polarity of the voltage output 115 before and after the power converter is turned off (e.g., corresponding to on and off-states of corresponding PWM signal). Therefore, the device current 14 before the power converter 12 is turned-off should also be sampled, as illustrated in the timing diagram 300.

The timing diagram 300 illustrates waveforms for signals similar to the timing diagram 200. For example, the timing diagram 300 illustrates waveforms for a PWM signal 303, a reset signal 306, the sensor output signal 315, a comparator output signal 360, and an FPGA sample signal 365. The controller 10 can be configured to generate the PWM signal 303 and the reset signal 306 for controlling the switching of the power converter 12, which can effectively drive the device current 14. The compensation circuit 140 can operate to effectively cancel the effect of the parasitic resistance 18 based on the PWM signal 303, by implementing the timing diagram 300 as described below.

The sensor output signal 315, the comparator output signal 360, and the FPGA sample signal 365 correspond to signals generated by the compensation circuit 140, for generating and modifying the compensation coefficient k. The sensor output signal 315 can correspond to the voltage output 115 that is generated by the op-amp 106. The comparator output signal 360 can correspond to the comparator output 160 that is generated by the comparator 143. The comparator output signal 360 can be used for determining the polarity of the sensor output signal 315 based on various samples of the FPGA sample signal 365 taken during the on-states and off-states of the PWM signal 303. For example, the FPGA sample signal 365 can include samples (e.g., “sample 1” corresponding to “Cₒ₁”) of the comparator output signal 360 gathered during the PWM signal 303 on-states and samples (e.g., “sample 2” corresponding to “Cₒ₂”) of the comparator output signal 360 gathered during the PWM signal 303 off-states. The processor 146 may gather the samples continuously over time for the length of the PWM signal 303, as illustrated in the timing diagram 300. The reset signal 306 can be used to synchronize the operation of the PWM signal 303 with the power converter 12 to reset internal states within the controller 10 and/or to reset operation of the current sensor 100.

If the polarity of the device current 14 is negative during the on-time of the PWM signal 303, the logic of the close-loop adjustment of the coefficient k should be reversed as compared to the close-loop adjustment algorithm implemented with the timing diagram 200 (FIG. 2). This logic for the close-loop adjustment of the compensation coefficient k, implementing the timing diagram 300, is shown in Table 1 below:

TABLE 1
Logic for Automatic Compensation Adjustment.

| Co1& Co2 | Status | Adjustment of k |
|---|---|---|
| Co1 > 0, Co2 > 0 | Under- | Increase k |
| | compensation | |
| Co1 > 0, Co2 < 0 | Over- | Decrease k |
| | compensation | |
| Co1 < 0, Co2 < 0 | Under- | Increase k |
| | compensation | |
| Co1 < 0, Co2 > 0 | Over- | Decrease k |
| | compensation | |

As described in Table 1 above, various polarities of the sensor output signal 315 identified by the samples of the comparator output signal 360 can signify a status of under-compensation or over-compensation, leading to the processor 146 automatically adjusting the compensation coefficient k. In some embodiments, a PID control algorithm can be implemented to achieve a balance between minimizing steady-state error and ensuring a robust dynamic response.

In one or more embodiments, the current sensor 100 can be designed to have the following parameters shown in Table 2:

TABLE 2
Parameters of the Current Sensor 100.

| Parameters | Values | |
|---|---|---|
| Parasitic Inductance L | 0.9 | nH |
| Parasitic Resistance R | Variable: 0.3-0.8 mΩ | |
| Integrator Resistance Rᵢ | 470 | Ω |
| Integrator Capacitance Cᵢ | 100 | pF |
| Compensation Resistance R₂ | 20 | kΩ |

| | |
|---|---|
| Coefficient k | 0.67-1.78 |
| Gain of sensor | 0.019 |
| Op-amp | LM7372 |

It should be noted that the parameters listed above in Table 2 are provided as way of a non-limiting example. The current sensor 100 can be implemented with other parameters although not listed above.

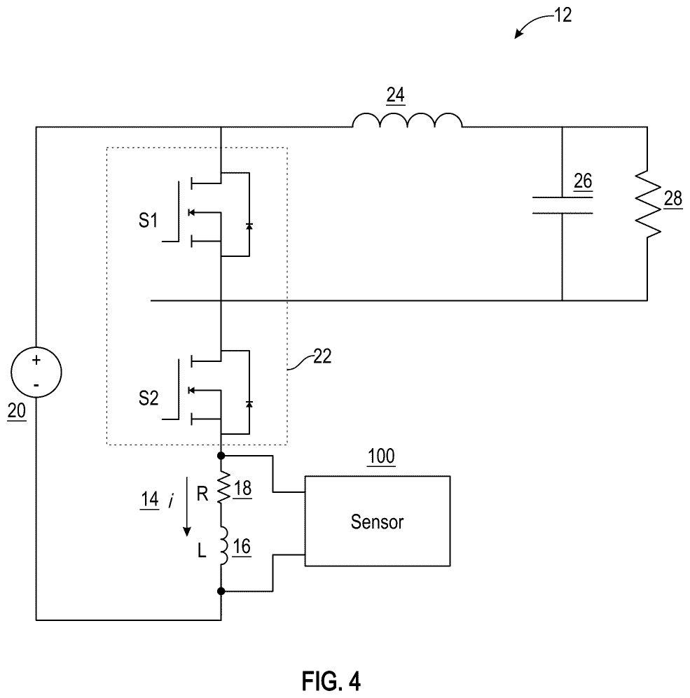

FIG. 4 depicts an example schematic of the power converter 12 connected to the current sensor 100, according to one or more embodiments of the present disclosure. In this example schematic, the power converter 12 is a buck converter including a voltage source (e.g., DC voltage source) 20, a set of switches 22, an inductor 24, a capacitor 26, and a resistor 28. The current sensor 100 is electrically coupled between the set of switches 22 and the voltage source 20. Specifically, the current sensor 100 is electrically coupled between a second switch S2 and the voltage source 20, to measure device current (e.g., the device current 14) flowing through the parasitic inductance 16, while adaptively compensating to cancel the effects of the parasitic resistance 18. Although the current sensor 100 is electrically coupled between the second switch S2 and the voltage source 20, the current sensor 100 can be electrically coupled to other traces, wires, wire bonds, or any other conductive components of the power converter 12 where the device current 14 is desired to be measured. For example, the current sensor 100 can be electrically coupled between the switches S1 and S2 of the set of switches 22 or between the switch S1 and the voltage source 20, among other locations.

In one experiment, for current reconstruction, a stray inductance of 0.9 nH was selected for the parasitic inductance 16 in series with the switch S2. The parasitic resistance 18 was selected as 0.45 mΩ, and the corresponding compensation coefficient k was selected initially as 0.7. With the compensation coefficient k set initially to 0.7, a current sensor error was detected for the current sensor 100 for the measurement of the current flowing from the switch S2, and the dynamic process of automatic compensation adjustment was initiated by the compensation circuit 140. By increasing the compensation coefficient k to 1.0, the compensation (e.g., error) between the device current 14 and the voltage output 115 (as measured across the parasitic inductance 16), caused by the parasitic resistance 18, was eliminated. For example, the voltage output 115 gradually converged to the correct value of the device current 14.

The bandwidth of the current sensor 100 can depend on the frequency-domain response of the connected trace of the power converter 12 and/or the sensing circuit 103. In various examples, the connected trace can be regarded as a pure inductor at high frequencies. Therefore, the bandwidth of the current sensor 100 is generally only dependent on the sensing circuit 103 and can be determined by the limited gain-bandwidth-product (GBW) of the op-amp 106. The compensation circuit 140, including the compensation resistor 155 and the compensation coefficient k, is used to compensate for the parasitic resistance 18 and can be ignored in the analysis for the determination of bandwidth of the current sensor 100.

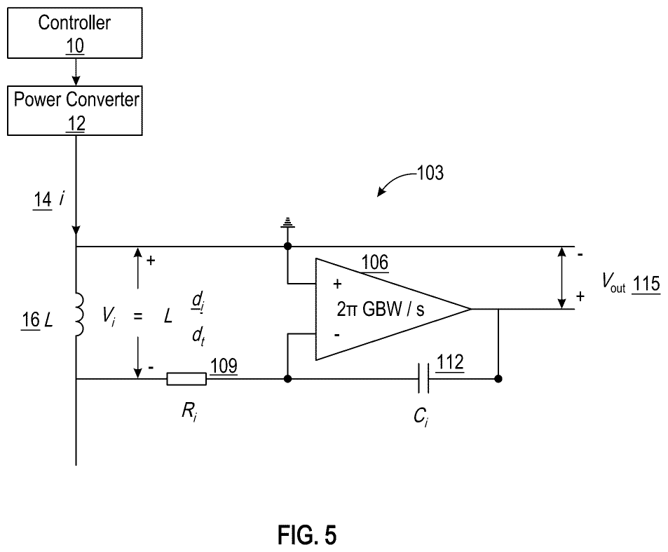

FIG. 5 depicts a resistor capacitor (RC) circuit for modeling the bandwidth of the current sensor 100 according to one or more embodiments of the present disclosure. As described above, the bandwidth of the current sensor 100 can be modeled according to an RC integrator circuit such as the sensing circuit 103 shown in FIG. 5. The compensation circuit 140 is removed from the circuit shown in FIG. 5 for the purposes of determining the bandwidth of the current sensor 100 only. The open-loop gain of the op-amp 106 can be reversely proportional to the frequency of operation for the sensing circuit 103. The transfer function from the device current 14 to the voltage output 115 is expressed based on equation (18) below:

$$\frac{{V}_{out}}{i} = \frac{L}{\frac{{R}_{i} {C}_{i}}{2 π \cdot GBW} s + {R}_{i} {C}_{i} + \frac{1}{2 π \cdot GBW}} \qquad ( 18 )$$

Equation 18 indicates that the limited gain-bandwidth product leads to a pole at a very high frequency, as shown in equation (19) below. This frequency can be configured to be a bandwidth of the current sensor 100.

$${f}_{bw} = \frac{2 π {R}_{i} {C}_{i} \cdot GBW + 1}{2 π {R}_{i} {C}_{i}} \qquad ( 19 )$$

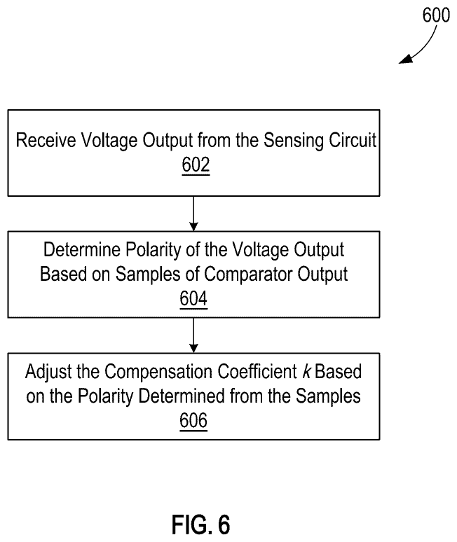

FIG. 6 is a flowchart of an example method 600 for adaptive compensation of parasitic resistance for the current sensor 100, according to one or more embodiments of the present disclosure. The compensation circuit 140 of the current sensor 100 can be configured to implement the method 600 for adaptive compensation for the parasitic resistance 18. At step 602, the compensation circuit 140 can be configured to receive the sensor output or the voltage output 115 from the op-amp 106 of the sensing circuit 103. For example, the voltage output 115 corresponds to the measurement of the device current 14 flowing through the connected trace between the power converter 12 and the sensing circuit 103 via the parasitic inductance 16. The sensing circuit 103 can be configured as an integrator circuit to determine an integration of the voltage presented across the parasitic inductance 16. In this manner, the op-amp 106 can be configured to generate the voltage output 115, as depicted in FIG. 1.

At step 604, the compensation circuit 140 can be configured to determine a polarity of the voltage output 115. The comparator 143 can be configured to receive the voltage output 115 and in response, generate the comparator output 160. The processor 146 can be configured to gather various samples of the comparator output 160 at the on-times and/or the off-times of the power converter 12, as directed by the controller 10. For example, referring back to FIG. 3, the processor 146 can be configured to gather various samples (e.g., the samples corresponding to “sample 1” and “sample 2”) of the comparator output signal 360 during both the on-times and the off-times of the power converter 12 as directed by the PWM signal 303. The processor 146 can be configured to determine the polarity of the voltage output 115 based on samples gathered from the comparator output 160. Based on the values of the comparator output 160 (as represented by the comparator output signal 360), the processor 146 can be configured to execute a closed-loop control algorithm of the compensation coefficient k.

At step 606, the processor 146 can be configured to adaptively adjust the compensation coefficient k based on the polarity determined from the samples of the comparator output 160. The dynamic adjustment of the compensation coefficient k can reduce or eliminate the error (e.g., compensation error) of the voltage output 115 as compared to the device current 14. Referring back to Table 1, if “sample 1” and “sample 2” of the comparator output signal 360 are both greater than zero, the voltage output 115 measured by the sensing circuit 103 is assumed to be under-compensated. To correct this under-compensation, the processor 146 can be configured to increase the compensation coefficient k. In another example, if sample 1 is greater than zero but sample 2 is less than zero, the voltage output 115 measured by the sensing circuit 103 is assumed to be over-compensated. To correct this over-compensation, the processor 146 can be configured to decrease the compensation coefficient k. In another example, if sample 1 and sample 2 are both less than zero, the voltage output 115 measured by the sensing circuit 103 is assumed to be under-compensated. To correct this under-compensation, the processor 146 can be configured to increase the compensation coefficient k. In yet another example, if sample 1 less than zero and sample 2 is greater than zero, the voltage output 115 measured by the sensing circuit 103 is assumed to be over-compensated, and the processor 146 can be configured to decrease the compensation coefficient k in response.

The current sensor 100 of the described embodiments can operate based on parasitic inductance that is inherent in all connected traces of the power converter 12 where device current may flow. The current sensor 100 can be used to reconstruct device current with numerous attributes such as high bandwidth, minimal spatial footprint, and non-intrusiveness. Additionally, the current sensor 100 provides various features such as dynamic and adaptive compensation for parasitic resistance, even when the exact value of the parasitic resistance is unknown in advance. The current sensor 100 offers a versatile and robust solution for accurate current measurement in power circuits in contrast to conventional current sensors such as shunt resistors, Rogowski coils, current transducers, and hall sensors, which all have limitations.

The features, structures, or characteristics described above may be combined in one or more embodiments in any suitable manner, and the features discussed in the various embodiments are interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims. If a component is described as having “one or more” of the component, it is understood that the component can be referred to as “at least one” component.

The terms “first,” “second,” etc. are used only as labels, rather than a limitation for a number of the objects. It is understood that if multiple components are shown, the components may be referred to as a “first” component, a “second” component, and so forth, to the extent applicable.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X; Y; Z; X or Y; X or Z; Y or Z; X, Y, or Z; etc.). Thus, such disjunctive language is not generally intended to, and should not, imply that certain embodiments require at least one of X, at least one of Y, or at least one of Z to each be present.

The flowchart of FIG. 6 is the functionality and operation of an implementation of portions of an application executed by processing circuitry or at least one hardware processor, such as in the processor 146. If embodied in software, each block may represent a module, segment, or portion of code that comprises program instructions to implement the specified logical function(s). The program instructions may be embodied in the form of source code that comprises human-readable statements written in a programming language or machine code that comprises numerical instructions recognizable by a suitable execution system such as a processor (e.g., a hardware processor) in a computer system or other system. The machine code may be converted from the source code, etc. If embodied in hardware, each block may represent a circuit or a number of interconnected circuits to implement the specified logical function(s).

Although the flowchart of FIG. 6 shows a specific order of execution, it is understood that the order of execution may differ from that which is depicted. For example, the order of execution of two or more blocks may be scrambled relative to the order shown. Also, two or more blocks shown in succession in FIG. 6 may be executed concurrently or with partial concurrence. Further, in some embodiments, one or more of the blocks shown in FIG. 6 may be skipped or omitted. In addition, any number of counters, state variables, warning semaphores, or messages might be added to the logical flow described herein, for purposes of enhanced utility, accounting, performance measurement, or providing troubleshooting aids, etc. It is understood that all such variations are within the scope of the present disclosure.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

Therefore, at least the following is claimed:

1. A current sensor for a power converter, comprising:
a sensing circuit configured to generate an output voltage based on a device current flowing through a power converter, the output voltage being representative of a measurement of the device current; and
a compensation circuit electrically coupled to the sensing circuit and comprising a compensation resistor and a processor, the compensation circuit configured to:
receive the output voltage; and
adjust an error of the output voltage as compared to the device current, the error caused by a parasitic resistance existing in the power converter.

2. The current sensor of claim 1, wherein:
the sensing circuit is an integrator circuit; and
the sensing circuit is configured to generate the output voltage based on integrating a voltage presented across a parasitic inductance existing in the power converter over a period of time.

3. The current sensor of claim 1, wherein, to adjust the error, the compensation circuit is further configured to:
determine a polarity of the output voltage; and
dynamically adjust the error based on the polarity of the output voltage.

4. The current sensor of claim 3, wherein, to dynamically adjust the error based on the polarity of the output voltage, the compensation circuit is further configured to:
generate an adjustable compensation coefficient; and
modify the adjustable compensation coefficient based on the polarity of the output voltage.

5. The current sensor of claim 4, wherein the compensation resistor in combination with the adjustable compensation coefficient substantially cancels the parasitic resistance.

6. The current sensor of claim 4, wherein, to modify the adjustable compensation coefficient based on the polarity, the compensation circuit is further configured to increase the adjustable compensation coefficient in response to the polarity being determined to be a positive value at an off-time of the power converter, the polarity being determined to be the positive value corresponding to a case of under-compensation of the output voltage as compared to the device current.

7. The current sensor of claim 4, wherein, to modify the adjustable compensation coefficient based on the polarity, the compensation circuit is further configured to decrease the adjustable compensation coefficient in response to the polarity being determined to be a negative value at an off-time of the power converter, the polarity being determined to be the negative value corresponding to a case of over-compensation of the output voltage as compared to the device current.

8. The current sensor of claim 4, wherein the processor is configured to generate and modify the adjustable compensation coefficient based on the polarity of the output voltage.

9. The current sensor of claim 3, wherein the polarity of the output voltage is determined at an off-time of the power converter.

10. The current sensor of claim 3, wherein the polarity of the output voltage is determined at both an off-time and an on-time of the power converter.

11. The current sensor of claim 3, wherein the error is dynamically adjusted based on a closed-loop control algorithm.

12. The current sensor of claim 1, wherein the current sensor is implemented in a printed circuit board (PCB).

13. The current sensor of claim 1, wherein the current sensor is electrically coupled between a first switch and a second switch of the power converter.

14. A method for adaptive compensation for a current sensor, comprising:
determining, by the current sensor, an output voltage based on a device current flowing through a power converter, the output voltage being representative of a measurement of the device current;
determining, by the current sensor, an error of the output voltage as compared to the device current, the error caused by a parasitic resistance existing in the power converter; and
adjusting, by the current sensor, the error dynamically in real-time so that the error between the output voltage and the device current is minimized.

15. The method of claim 14, further comprising:
determining, by the current sensor, a polarity of the output voltage, wherein the error is adjusted based on the polarity of the output voltage.

16. The method of claim 15, wherein adjusting the error further comprises:
generating an adjustable compensation coefficient; and
modifying the adjustable compensation coefficient based on the polarity of the output voltage.

17. The method of claim 16, wherein modifying the adjustable compensation coefficient based on the polarity comprises increasing the adjustable compensation coefficient in response to the polarity being determined to be a positive value at an off-time of the power converter, the polarity being determined to be the positive value corresponding to a case of under-compensation of the output voltage as compared to the device current.

18. The method of claim 16, wherein modifying the adjustable compensation coefficient based on the polarity comprises decreasing the adjustable compensation coefficient in response to the polarity being determined to be a negative value at an off-time of the power converter, the polarity being determined to be the negative value corresponding to a case of over-compensation of the output voltage as compared to the device current.

19. The method of claim 16, wherein modifying the adjustable compensation coefficient based on the polarity comprises increasing the adjustable compensation coefficient in response to the polarity being determined to be a positive value at an off-time of the power converter and a positive value at an on-time of the power converter, the polarity being determined to be the positive value at the off-time and the on-time corresponding to a case of under-compensation of the output voltage as compared to the device current.

20. The method of claim 14, wherein the current sensor comprises:
a sensing circuit configured to generate the output voltage; and
a compensation circuit electrically coupled to the sensing circuit and configured to determine and adjust the error, the compensation circuit comprising a compensation resistor and a processor.
